(19) United States
(12) Patent Application Publication
(10) Pub. No.: US 2003/0088959 A1
(43) Pub. Date: May 15, 2003

(54) Wafer transfer apparatus

(75) Inventor: Masaki Tsujimoto, Tokyo (JP)

Correspondence Address: Russell D. Orkin, 700 Koppers Building, 436 Seventh Avenue, Pittsburgh, PA, 15219-1818, US

(73) Assignee: LINTEC CORPORATION

(21) Appl. No.: 10/292,874

(22) Filed: Nov. 12, 2002

(30) Foreign Application Priority Data
Nov. 13, 2001 (JP) 2001-347617

(51) Int. Cl. H01L 21/00

(52) U.S. Cl. 29/25.01

(57) ABSTRACT

A wafer transfer apparatus comprising a first ultraviolet irradiation unit capable of irradiating and exposing ultraviolet light to a protective tape; a positioning unit capable of effecting positioning of a wafer; a mount unit capable of uniting the wafer with a ring frame; a protective tape peeling unit capable of peeling a protective tape from the wafer surface; and a second ultraviolet irradiation unit capable of irradiating and exposing ultraviolet light to a dicing tape. The provided wafer transfer apparatus is one of enhanced general applicability which can be applied to not only the conventional postdicing processing but also a predicing processing, and which, irrespective of the types of employed protective tape and dicing tape, can continuously and automatically transfer the wafer having the protective tape stuck thereto to the dicing tape and the ring frame and further peel the protective tape from the wafer surface.

### FIELD OF THE INVENTION

The present invention relates to a wafer transfer apparatus capable of, in a process for manufacturing small electronic components such as semiconductor chips, transferring (re-sticking) a wafer having a protective tape stuck thereto to a ring frame and a dicing tape and peeling the protective tape from the wafer.

### BACKGROUND OF THE INVENTION

In the conventional process for producing a wafer of, for example, a semiconductor such as silicon, a wafer is prepared in the form of a disk of large diameter. A circuit pattern is formed on a surface of the wafer, and the circuit pattern surface is protected with a protective tape. The back of the wafer is ground, and the protective tape is peeled from the wafer surface. The thus obtained semiconductor wafer is stuck to a ring frame via a pressure sensitive adhesive sheet, and cut and divided into dice (diced) with the use of a dicing cutter so that a multiplicity of chips are obtained. Thereafter, the chips in that state are subjected to subsequent cleaning, drying and die bonding steps.

Recently, the reduction of the thickness of semiconductor chips such as IC cards is increasingly demanded. The demand for extremely thin semiconductor chips whose thickness has been reduced to about 50 to 100 μm from the conventional 300 to 400 μm is increasing. However, when such extremely thin wafers are produced by the above back grinding process, there would be the fear of carrying failure or wafer cracking caused by wafer warpage during, for example, protective tape peeling, wafer mounting and dicing steps.

The process known as “predicing” as disclosed in Japanese Patent Laid-open Publication No. 5(1993)-335411 has been proposed for coping with the above problem. In this process, a wafer is diced from its surface formed with a circuit to given depth in the direction of wafer thickness to thereby form grooves with bottoms in a dice pattern. Subsequently, a protective tape is stuck to the wafer surface, and the wafer back is ground to the grooves with bottoms so that the wafer is divided into a multiplicity of chips. Thereafter, the wafer having the protective tape stuck thereto is stuck to a ring frame, and is subjected to subsequent cleaning, drying and die bonding steps.

However, in any of the above processes, the current situation is that peeling of a protective tape and sticking of a dicing tape to a wafer are carried out by separate devices. Thus, wafer conveying between separate devices is needed, and this is generally performed by placing wafers in a container such as a wafer carrier provided with multi-stage wafer accommodation parts and transporting the container to subsequent-step device.

Currently, however, the thickness of wafers tends to become smaller and, on the other hand, the diameter of wafers tends to become larger. The centers of the wafers sink and are deformed by their own weights in the carrier, depending on the ratio of wafer diameter to thickness. As a result, automatic takeout from the carrier and placing in the carrier is difficult. Even if automatic takeout and placing can be conducted, there would be the fear of wafers contacting the carrier to thereby suffer breakage and damaging.

In the above predicing process, the wafers are in the state of being divided into a multiplicity of chips and fixed by a protective tape constituted of a flexible film, so that, at the time of handling, there would be the fear of neighboring chips contacting each other to thereby suffer breakage.

In these circumstances, a wafer transfer apparatus capable of, not only continuously and automatically transferring wafers having been divided into a multiplicity of chips by predicing and having a protective tape stuck thereto to a dicing tape and ring frames, but also peeling the protective tape from the wafers so as to enable accommodating the wafers in a carrier was proposed in Japanese Patent Laid-open Publication No. 2000-68293.

However, in the wafer transfer apparatus disclosed in Japanese Patent Laid-open Publication No. 2000-68293, the processed wafers are those having been divided into a multiplicity of chips by predicing and having a protective tape stuck thereto. Further, the protective tape for use therein is one having an ultraviolet curable pressure sensitive adhesive, and after irradiating the protective tape with ultraviolet light, the protective tape is peeled from the wafer surface in a protective tape peeling unit.

Accordingly, in the wafer transfer apparatus disclosed in Japanese Patent Laid-open Publication No. 2000-68293, the processed wafers are limited to those having been divided into a multiplicity of chips by predicing. Furthermore, the type of protective tape for use therein is limited to one having an ultraviolet curable pressure sensitive adhesive.

As a result, for example, the wafer transfer apparatus disclosed in Japanese Patent Laid-open Publication No. 2000-68293 cannot be applied to:

(1) in the instance in which both a protective tape and a dicing tape are those having an ultraviolet curable pressure sensitive adhesive, and in which the wafer having been divided into a multiplicity of chips by predicing is united with a ring frame via a dicing tape with the use of a wafer transfer apparatus and in which chips are picked up (i.e. die bonding) after this formation of unification of a wafer;

(2) in the instance in which both a protective tape and a dicing tape which are not those having an ultraviolet curable pressure sensitive adhesive and are common pressure sensitive adhesive tape;

(3) in the instance in which a protective tape is one having an ultraviolet curable pressure sensitive adhesive while a dicing tape is not one having an ultraviolet curable pressure sensitive adhesive, and the dicing tape is common pressure sensitive adhesive tape;

(4) in the instance in which a protective tape is not one having an ultraviolet curable pressure sensitive adhesive and is common pressure sensitive adhesive tape while a dicing tape is one having an ultraviolet curable pressure sensitive adhesive; and

(5) in the instance in which conventional wafer not having been diced into a multiplicity of chips is diced, after sticking the wafer to a ring frame by means of a pressure sensitive adhesive sheet (postdicing). Therefore, the wafer transfer apparatus disclosed in Japanese Patent Laid-open Publication No. 2000-68293 lacks general applicability.

Moreover, the use of the wafer transfer apparatus disclosed in Japanese Patent Laid-open Publication No. 2000-68293 has been limited to, for example, wafers having been prediced by a grinder joined to the wafer transfer apparatus (inline docking) That is, it is impracticable to use this wafer transfer apparatus alone without being joined with a grinder as an off-line (stand alone) capable of taking out wafers from a wafer cassette or wafer packing container wherein wafers are accommodated and processing them. Thus, the wafer transfer apparatus disclosed in Japanese Patent Laid-open Publication No.2000-68293 lacks general applicability.

### OBJECT OF THE INVENTION

Taking these current circumstances into account, an object of the present invention is to provide a wafer transfer apparatus capable of, not only continuously and automatically transferring wafers having a protective tape stuck thereto to a dicing tape and ring frames, but also peeling the protective tape from the wafers, irrespective of the types of protective tape and dicing tape employed. The wafer transfer apparatus can be applied to both conventional postdicing and predicing, thus being excellent in general applicability.

Another object of the present invention is to provide a wafer transfer apparatus which can be joined with a grinder (inline docking) so as to enable use of prediced wafers and which can also be used alone without being joined with a grinder as an off-line (stand alone) capable of taking out wafers from a wafer cassette wherein wafers are accommodated or a wafer packing container wherein wafers are piled one upon another and accommodated and processing them, thus being excellent in general applicability.

### SUMMARY OF THE INVENTION

The present invention has been made with a view toward resolving the above problems of the prior art and attaining the above objects. According to the present invention, there is provided a wafer transfer apparatus for sticking a wafer, in which a protective tape is stuck to its surface, to a ring frame by means of a dicing tape, the wafer transfer apparatus comprising:

a first ultraviolet irradiation unit capable of irradiating and exposing ultraviolet light to the protective tape;

a positioning unit capable of disposing a wafer having a protective tape stuck to a surface thereof on a positioning table and conducting a position regulation of the wafer in longitudinal and lateral directions and direction of rotation to thereby locate the wafer at given reference position;

a mount unit capable of disposing on a mount table the wafer having the protective tape stuck thereto after having been located at the given reference position by the positioning unit, and capable of sticking a dicing tape to both the wafer at its back and a ring frame arranged so as to surround the wafer, thereby uniting the wafer and the ring frame together;

a protective tape peeling unit capable of disposing on a protective tape peeling table the wafer having the dicing tape stuck to the back thereof and thus having been united with the ring frame by the mount unit, capable of bonding an end of a peeling tape to an end of the protective tape provided on the surface of the wafer, and capable of pulling the peeling tape so that the protective tape is peeled from the wafer surface; and

a second ultraviolet irradiation unit capable of irradiating and exposing ultraviolet light to the dicing tape of the wafer having been united with the ring frame by means of the dicing tape after peeling of the protective tape from the wafer surface by the protective tape peeling unit.

By virtue of the above construction of the wafer transfer apparatus, the division lines of chipped wafer is recognized and a position regulation of the wafer in longitudinal and lateral directions (X- and Y-directions) and direction of rotation (θ-direction) is conducted so that the wafer at given reference position is located. As a result, at the diebonding step, accurate diebonding can be effected. Also, the relevant transfer operation and protective tape peeling operation can be continuously carried out without conveyance using a wafer carrier, so that the breakage, damage or cracking of wafer can be avoided.

Moreover, where the protective tape is one having an ultraviolet curable pressure sensitive adhesive, the adherence of the protective tape can be lowered by exposing the protective tape to ultraviolet light with the use of the first ultraviolet irradiation unit. As a result, in the step of peeling the protective tape, the protective tape can be easily peeled from the wafer without the occurrence of breakage, damage or cracking of wafer.

Further, when the dicing tape is one having an ultraviolet curable pressure sensitive adhesive, the adherence of the dicing tape can be lowered by exposing the dicing tape to ultraviolet light with the use of the second ultraviolet irradiation unit. As a result, in the subsequent pickup step wherein, after the division into a multiplicity of chips, the chips are picked up, the chips can be easily picked up from the dicing tape without the occurrence of breakage, damage or cracking of chips.

The wafer transfer apparatus of the present invention is preferably so constructed wherein selection from among performing both exposure of the protective tape to ultraviolet light by the first ultraviolet irradiation unit and exposure of the dicing tape to ultraviolet light by the second ultraviolet irradiation unit, performing either of the exposures and not performing both of the exposures is operated.

Thus, the present invention enables selectively performing exposure of the protective tape to ultraviolet light by means of the first ultraviolet irradiation unit and exposure of the dicing tape to ultraviolet light by means of the second ultraviolet irradiation unit. Therefore, the present invention can be applied to not only the conventional postdicing processing but also the predicing processing. Moreover, irrespective of the types of employed protective tape and dicing tape, not only the wafer having the protective tape stuck thereto can be continuously and automatically transferred to the dicing tape and the ring frame without the occurrence of breakage, damage or cracking of wafer, but also detaching of the protective tape can be accomplished. Therefore, the present invention ensures enhanced general applicability.

Another preferred form of wafer transfer apparatus according to the present invention is one wherein the protective tape is one having an ultraviolet curable pressure sensitive adhesive, and ultraviolet light is exposed to the protective tape by the first ultraviolet irradiation unit.

By virtue of this construction, the exposure of the protective tape to ultraviolet light by means of the first ultraviolet irradiation unit enables lowering the adherence of the protective tape. As a result, in the step of peeling the protective tape, the protective tape can be easily peeled from the wafer without the occurrence of breakage, damage or cracking of wafer.

An also preferred form of wafer transfer apparatus according to the present invention is one wherein the dicing tape is one having an ultraviolet curable pressure sensitive adhesive, and ultraviolet light is exposed to the dicing tape by the second ultraviolet irradiation unit.

By virtue of this construction, the exposure of the dicing tape to ultraviolet light by means of the second ultraviolet irradiation unit enables lowering the adherence of the dicing tape. As a result, in the subsequent pickup step wherein, after the division into a multiplicity of chips, the chips are picked up, the chips can be easily picked up from the dicing tape without the occurrence of breakage, damage or cracking of chips.

A further preferred form of wafer transfer apparatus according to the present invention is one wherein the wafer is one having been divided into a multiplicity of chips and having the protective tape stuck to the surface thereof, and both exposure of the protective tape to ultraviolet light by the first ultraviolet irradiation unit and exposure of the dicing tape to ultraviolet light by the second ultraviolet irradiation unit are operated.

By virtue of this construction, the exposure of the protective tape to ultraviolet light by means of the first ultraviolet irradiation unit enables lowering the adherence of the protective tape. As a result, in the step of peeling the protective tape, the protective tape can be easily peeled from the wafer having been divided into chips without the occurrence of breakage, damage or cracking of chips attributable to collision of chips.

Furthermore, the exposure of the dicing tape to ultraviolet light by means of the second ultraviolet irradiation unit enables lowering the adherence of the dicing tape. As a result, in the subsequent pickup step wherein, after the division into a multiplicity of chips, the chips are picked up, the chips can be easily picked up from the dicing tape without the occurrence of breakage, damage or cracking of chips.

Still further, a preferred form of wafer transfer apparatus according to the present invention is one wherein the wafer is one not having been divided into a multiplicity of chips but having the protective tape stuck to the surface thereof, and only exposure of the protective tape to ultraviolet light by the first ultraviolet irradiation unit is operated.

By virtue of this construction, even in the conventional postdicing processing, the exposure of the protective tape to ultraviolet light by means of the first ultraviolet irradiation unit enables lowering the adherence of the protective tape. As a result, in the step of peeling the protective tape, the protective tape can be easily peeled from the wafer without the occurrence of breakage, damage or cracking of wafer.

Furthermore, the second ultraviolet irradiation unit is not operated, so that, at the time of dicing, dicing can be performed with the adherence between dicing tape and wafer maintained. Therefore, wafer breakage or cracking at the dicing can be avoided.

Still further, another form of wafer transfer apparatus according to the present invention is one wherein conveyance means for conveying wafers to be processed from outside is attached to the first ultraviolet irradiation unit.

By virtue of this construction, for example, the wafer transfer apparatus can be joined with a grinder (inline docking) so as to enable use of wafers prediced by the grinder.

The wafer transfer apparatus of the present invention may be one wherein the first ultraviolet irradiation unit is provided with a wafer conveyance unit capable of taking out wafers from a wafer cassette wherein wafers are accommodated, and capable of carrying the wafers to the first ultraviolet irradiation unit.

By virtue of this construction, the wafer transfer apparatus can be used alone without being joined with a grinder as an off-line (stand alone) capable of taking out wafers from a wafer cassette wherein wafers are accommodated and processing them.

Also, the wafer transfer apparatus of the present invention may be one wherein the first ultraviolet irradiation unit is provided with wafer takeout means capable of taking out wafers from a wafer packing container wherein wafers are accommodated, and capable of delivering the wafers to the wafer conveyance unit.

By virtue of this construction, the wafer transfer apparatus can be used alone without being joined with a grinder as an off-line (stand alone) capable of taking out wafers from a wafer packing container wherein wafers are accommodated and processing them.

### BRIEF DESCRIPTION OF THE DRAWING

FIG. 1 is a plan of the entirety of one form of wafer transfer apparatus according to the present invention;

FIG. 2 is a sectional view of one form of wafer (prediced) for use in the present invention;

FIG. 3 is a sectional view of another form of wafer (wafer for postdicing) for use in the present invention;

FIG. 4 is a partial enlarged plan showing first wafer supply unit, first ultraviolet irradiation unit and positioning unit sections of the wafer transfer apparatus of the present invention;

FIG. 5 is a partial enlarged plan showing mount unit, protective tape peeling unit and second ultraviolet irradiation unit sections of the wafer transfer apparatus of the present invention;

FIG. 6 is a partial enlarged top view showing first wafer supply unit and ejection pusher unit sections of the wafer transfer apparatus of the present invention;

FIG. 7 is a sectional view of a sticking item, the sticking item comprising a wafer stuck to a ring frame, attracted to a mount table by suction by the wafer transfer apparatus of the present invention;

FIG. 8(A), (B) and (C) are schematic partial enlarged side views for explaining the motion of a mount unit included in the wafer transfer apparatus of the present invention;

FIG. 9 is a partial enlarged side view for explaining the motion of a protective tape peeling unit included in the wafer transfer apparatus of the present invention;

FIG. 10 is another partial enlarged side view for explaining the motion of a protective tape peeling unit included in the wafer transfer apparatus of the present invention;

FIG. 11 is a further partial enlarged side view for explaining the motion of a protective tape peeling unit included in the wafer transfer apparatus of the present invention;

FIG. 12 is still a further partial enlarged side view for explaining the motion of a protective tape peeling unit included in the wafer transfer apparatus of the present invention;

FIG. 13 is still a further partial enlarged side view for explaining the motion of a protective tape peeling unit included in the wafer transfer apparatus of the present invention;

FIG. 14 is a partial enlarged side view for explaining the motion of a peeling head part of the protective tape peeling unit;

FIG. 15 is an enlarged sectional view for explaining the motion of peeling of a protective tape from a sticking item including prediced wafer by the protective tape peeling unit; and

FIG. 16 is an enlarged sectional view for explaining the motion of peeling of a protective tape from a sticking item including a wafer for postdicing by the protective tape peeling unit.

### DETAILED DESCRIPTION OF THE INVENTION

One form (example) of wafer transfer apparatus according to the present invention will be described below with reference to the appended drawings.

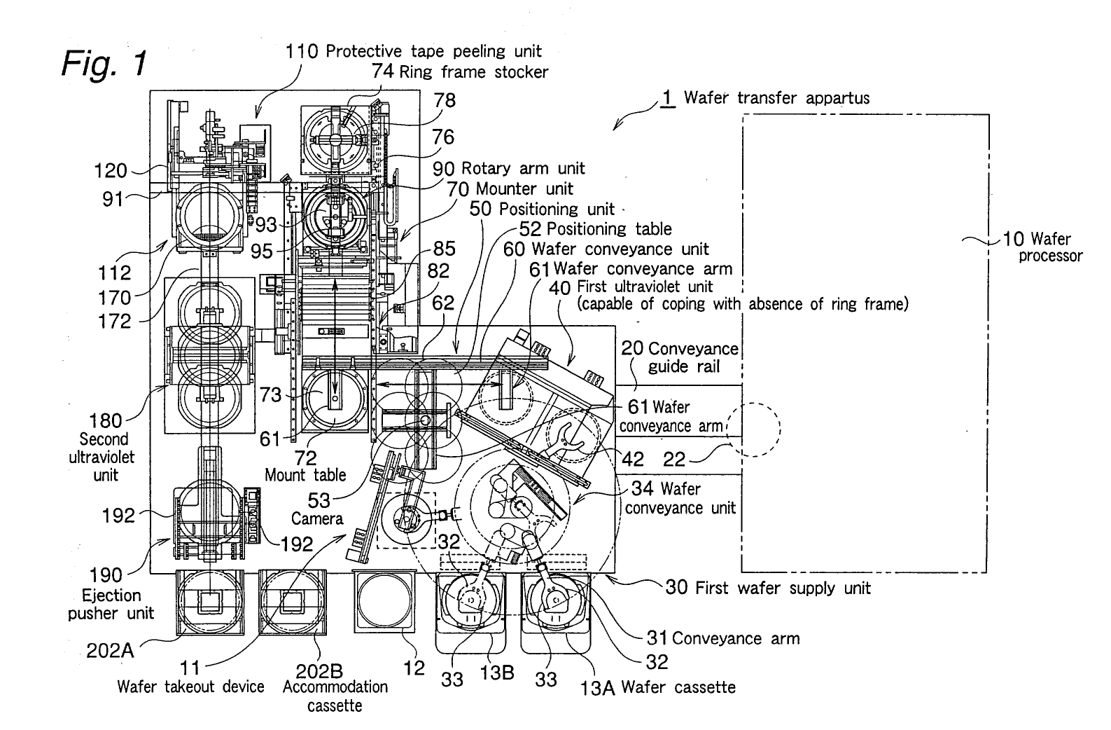

FIG. 1 is a top view of the entirety of one form of wafer transfer apparatus according to the present invention.

As shown in FIG. 1, numeral 1 generally denotes one form of wafer transfer apparatus according to the present invention.

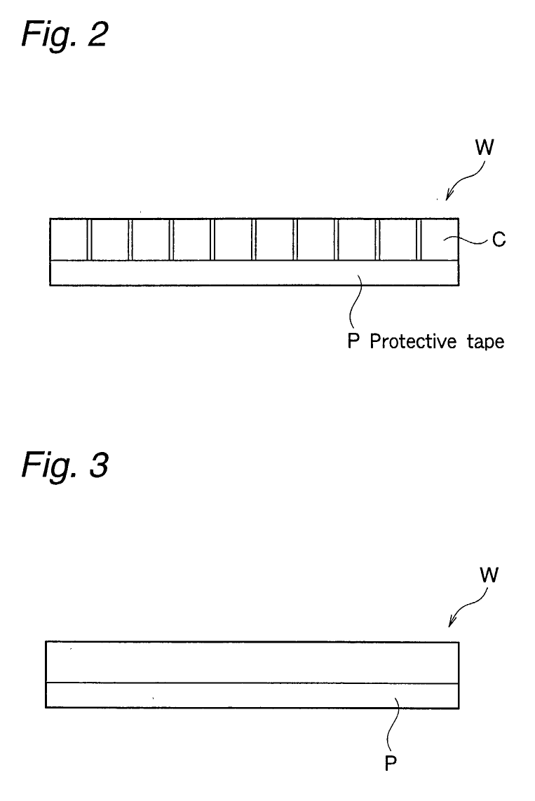

The wafer transfer apparatus 1 processes, for example, wafer W having been divided into a multiplicity of chips and provided with a protective tape stuck thereto. This wafer W can be obtained by using a wafer processor 10 for processing wafers in advance such as a grinder (not shown) in accordance with the predicing method. In this wafer processor 10, as shown in FIG. 2, a wafer is diced from its surface provied with a circuit to given depth in the direction of wafer thickness so that grooves with bottoms in a dice pattern. Subsequently, protective tape P is stuck to the wafer surface and thereafter the wafer back is ground to the grooves with bottoms so that the wafer is divided into a multiplicity of chips.

Embodiment of the present invention wherein the above wafer W is used will first be described below.

In the case of inline docking, the wafer W is fed to the main structure of wafer transfer apparatus 1 by means of, for example, a separate carrier arm (not shown). Specifically, as shown in FIG. 1, the wafer W after grinding of the wafer back is transferred on to table-shaped conveyance member 22. This conveyance member 22 is movable along conveyance guide rail 20. This conveyance member 22 consists of a suction member constituted of, for example, a porous ceramic, so that the entire surface of protective tape P side of wafer W is attracted and immobilized by the action of negative pressure.

The wafer W thus having been conveyed by the conveyance member 22 is transferred onto supply table 42 of first ultraviolet irradiation unit 40 so that the protective tape P side of wafer W is positioned below, and attracted by suction.

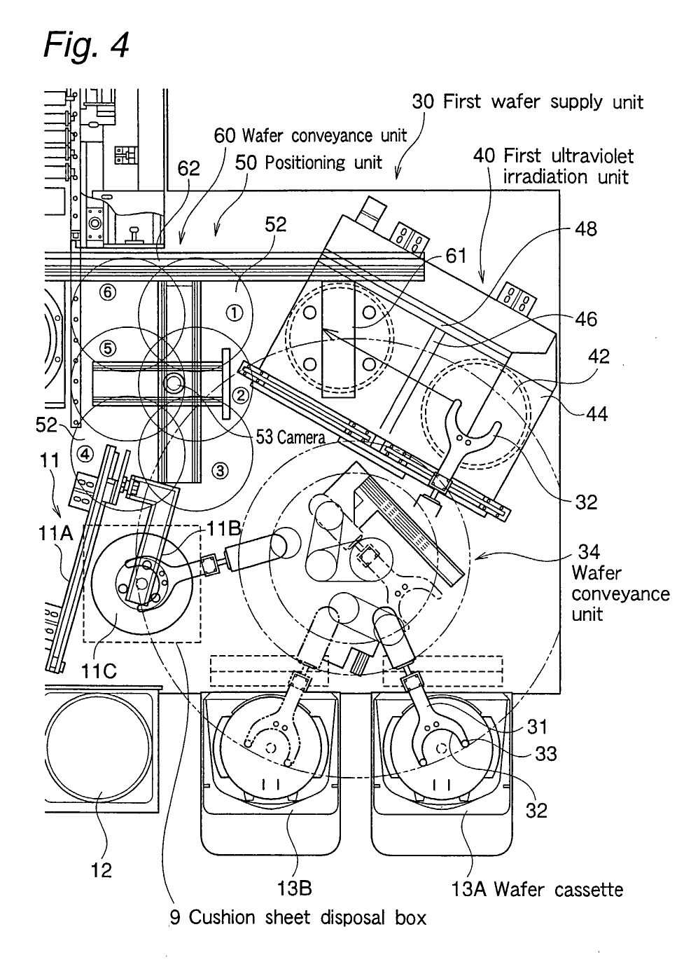

The first ultraviolet irradiation unit 40, as shown in FIG. 4, is provided with ultraviolet lamp chamber 44. The ultraviolet lamp chamber 44 at its upper portion is provided with a movable shutter (not shown) which can be opened and closed. The ultraviolet lamp chamber 44 at its lower portion is provided with ultraviolet lamp 46.

The wafer W having been transferred onto the supply table 42 is moved in the arrow direction of FIG. 4 by means of conveyance arm 48 after closing of the shutter (not shown) While the wafer W is being moved, ultraviolet light is irradiated upward by the ultraviolet lamp 46 in combination with a reflecting mirror (not shown), so that the protective tape P side of wafer W is exposed to ultraviolet light.

Where an ultraviolet curable pressure sensitive adhesive is used as the pressure sensitive adhesive of the protective tape P for sticking and sustaining the wafer W which has been divided into a multiplicity of chips, the irradiation of ultraviolet light is performed to cure the pressure sensitive adhesive so that the bonding strength of pressure sensitive adhesive is reduced. As a result, the protective tape P can be easily peeled from the wafer W which has been divided into a multiplicity of chips.

On the other hand in case of an off-line (stand alone), in which the wafer transfer apparatus is used alone without being connected with the above grinder or other wafer processor, wafers W are taken out from wafer cassettes 13A, 13B wherein wafers W are accommodated or from wafer packing container 12 wherein wafers W are piled one upon another and accommodated and the wafers W are processed. In this type of off-line using, each wafer W is processed in the following manner.

Namely, as shown in FIG. 1, wafer conveyance unit 34 of first wafer supply unit 30 is adapted to make a circular arc rotation as shown by an alternate long and two short dashes line of FIG. 1. Conveyance arm 31 thereof is adapted to be freely movable as shown in FIG. 4.

The conveyance arm 31 of the wafer conveyance unit 34 of the first wafer supply unit 30 has U-shaped distal end portion 32. This distal end portion 32 has suction members 33 so that the wafer W can be attached by means of the suction members 33. These suction members 33 are provided with suction holes (not shown). These suction holes are connected to a vacuum source such as a vacuum pump so that a negative pressure is generated. As a result, the surface side protective tape P of wafer W is attracted and sustained by the negative pressure. By virtue of this construction, the breakage damaging of the chips of wafer W can be prevented.

Where the wafer transfer apparatus is used alone as an off-line (stand alone) capable of taking out wafers W from wafer cassettes 13A, 13B wherein wafers W are accommodated and processing them, a plurality of wafers W with given spacings are arranged on shelves of the wafer cassettes 13A or 13B. In this case, the side of wafers W having the protective tape P stuck thereto is positioned below.

As shown in FIG. 3, in these wafer cassettes 13A, 13B, wafers W not prediced (FIG. 2) are accommodated as described later.

Each wafer W having been attracted and delivered by the wafer conveyance unit 34 of the first wafer supply unit 30 is conveyed to the first ultraviolet irradiation unit 40.

That is to say, the conveyance arm 31 of the wafer conveyance unit 34 is rotated so that each wafer W is conveyed to the first ultraviolet irradiation unit 40.

Then, in the same manner as in the inline docking, the surface side, namely, protective tape P side of wafer W is exposed to ultraviolet light irradiated from the ultraviolet lamp.

On the other hand, where the wafer transfer apparatus is used alone as an off-line (standalone) capable of taking out wafers W (FIG. 3) from wafer packing container 12 wherein wafers W are piled one upon another and accommodated and processing them, wafers W accommodated in the wafer packing container 12 are used. In this wafer packing container 12, wafers W are piled one upon another with cushion sheets (not shown) interposed between neighboring wafers W in order to protect the circuit surface of wafers W.

As shown in FIGS. 1 and 4, the wafer transfer apparatus includes the wafer packing container 12 wherein wafers W are piled one upon another with cushion sheets (not shown) interposed between neighboring wafers W in order to protect the circuit surface of wafers W and accommodated. Further, the wafer transfer apparatus includes wafer takeout device 11. This wafer takeout device 11 has wafer conveyance arm 11B which can move freely along wafer takeout rail 11A. This wafer conveyance arm 11B is provided with suction member 11C, whereby the back surface of each wafer W accommodated in the wafer packing container 12 is attracted through the action of a negative pressure. Thereafter, the wafer W is moved by the wafer conveyance arm 11B and delivered to the wafer conveyance unit 34 of the first wafer supply unit 30.

The wafer W thus having been delivered to the wafer conveyance unit 34 is conveyed to the first ultraviolet irradiation unit 40 by means of the conveyance arm 31 of the wafer conveyance unit 34 in the above-mentioned manner.

In that instance, as described later, the wafers W accommodated in the wafer packing container 12 are, for example, common wafers W not divided into a multiplicity of chips, which wafers W have protective tapes P stuck to the circuit surface thereof and are piled one upon another with cushion sheets interposed between neighboring wafers W and accommodated. The wafers W are moved into the first ultraviolet irradiation unit 40, wherein the wafers W are exposed to ultraviolet light.

In this wafer transfer apparatus, the cushion sheet (not shown) interposed between neighboring wafers W, is taken out and disposed in cushion sheet disposal box 9 by the wafer conveyance arm 11B of the wafer takeout device 11 after the takeout of each wafer W from the wafer packing container 12.

Each wafer W thus having been exposed to ultraviolet light while passing through the ultraviolet irradiation unit 40, as shown in FIGS. 1 and 4, is attracted and sustained by wafer conveyance arm 61 of wafer conveyance unit 60. As a result, the wafer W is conveyed to positioning unit 50 and delivered to and disposed on positioning table 52 so that the circuit surface of wafer W is located up.

The positioning table 52, like the aforementioned wafer W conveyance member 22, is so constructed as to attract, sustain and immobilize the protective tape P side of wafer W through the action of a negative pressure.

In the positioning unit 50 of the above construction, with the use of image recognition camera 53 arranged above the positioning unit 50, each wafer W is located at given reference position by carrying out rotation and position regulation of the positioning table 52 in the longitudinal and lateral directions (XY directions), toward positions (1) to (6) of FIG. 4 and in the direction of rotation (θ direction) along the division line (dicing line) of wafer W. As a result, accurate die bonding can be effected in the subsequent die bonding step not shown. With respect to the method of position regulation, the position regulation can also be performed upon recognition of the position of, for example, an orientation flat or notch of wafer W.

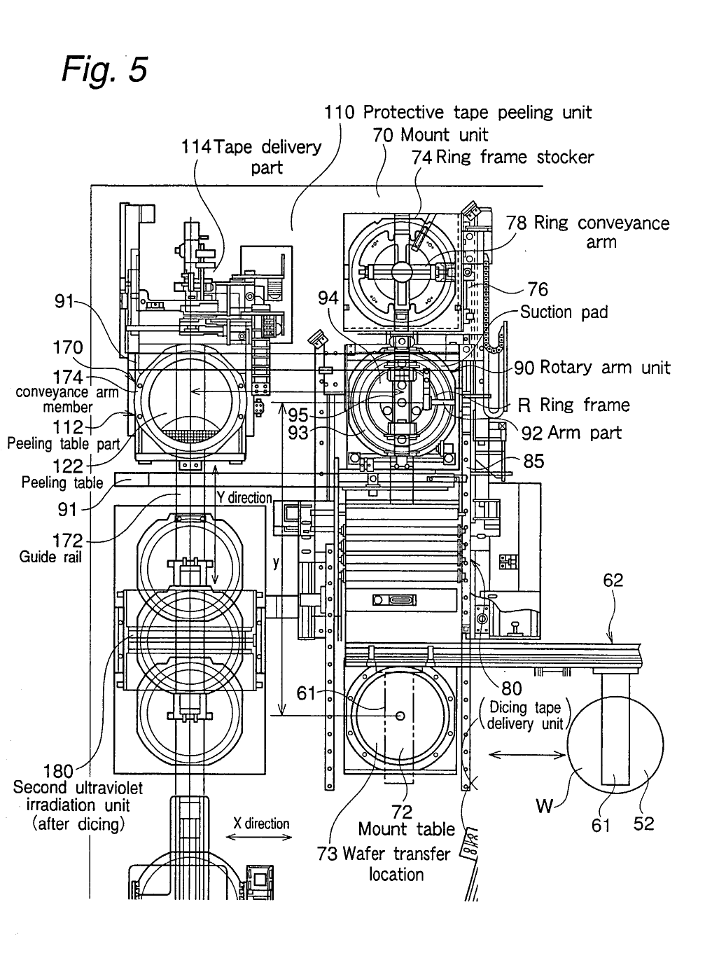

The wafer W thus having been positioned by the positioning table 52 of the positioning unit 50 is conveyed by means of the conveyance arm 61 of the wafer conveyance unit 60. As a result, the wafer W with its back side located up is transferred onto mount table 72 of mount unit 70 (FIGS. 1 and 5).

The wafer conveyance unit 60, as shown in FIGS. 1 and 4, is provided with the conveyance arm 61 which can be moved along guide rail 62 which extend from the positioning unit 50 to the mount unit 70. This conveyance arm 61 is provided with vertically movable driving means (not shown) so that any impact as caused at the time of attracting and sustaining is lowered.

In the wafer conveyance unit 60 of the above structure, the conveyance arm 61 attracts and sustains the wafer W having been positioned on the positioning table 52 and is moved along the guide rail 62 until reaching a wafer transfer position. In this position, the wafer W is transferred onto the mount table 72 of the mount unit 70.

The mount unit 70, as shown in FIGS. 1 and 5, is provided with the mount table 72 and, at a side opposite thereto, is provided with ring frame stocker 74 wherein a multiplicity of ring frames R are accommodated.

As shown in FIGS. 1 and 5, guide rail 76 extending in the cross direction (Y-axis direction) from the mount table 72 to the ring frame stocker 74 is provided above the ring frame stocker 74. The wafer transfer apparatus includes ring conveyance arm 78 which is movable along the guide rail 76. The ring conveyance arm 78 at its distal end has a vacuum suction part provided with vacuum pad (not shown).

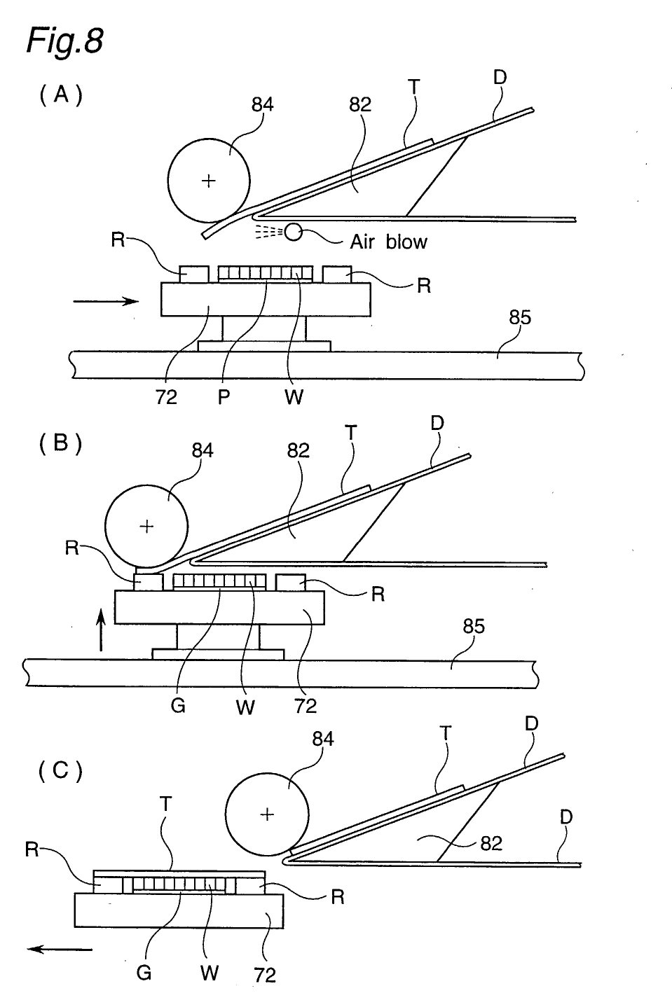

This mount table 72 of the mount unit 70 is moved to ring frame disposing position 93 along guide rail 85 (FIG. 8) and is held waiting. Meanwhile, the ring conveyance arm 78 is moved to position right above the ring frame stocker 74. Thus, the ring conveyance arm 78 attracts and sustains ring frame R and the ring conveyance arm 78 is moved along the guide rail 76 to position right above the mount table 72. As a result, the ring frame R is disposed on the mount table 72 in advance.

The mount table 72 thus having the ring frame R disposed in given position in advance is moved along the guide rail 85 to wafer transfer position 73.

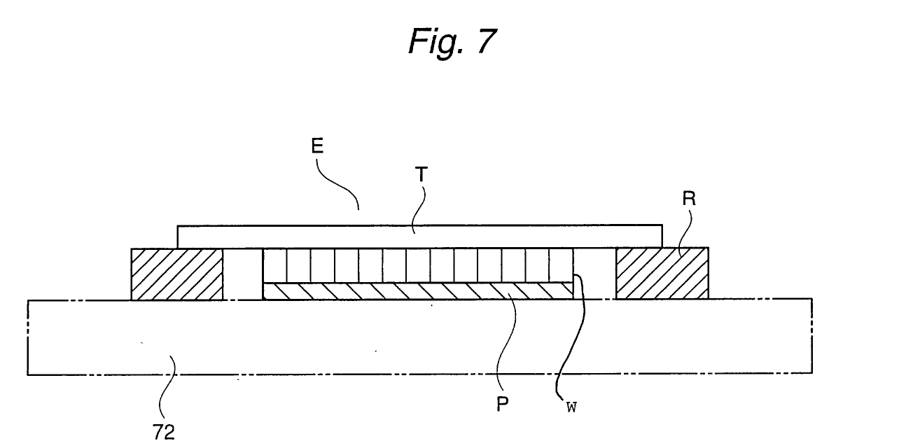

Consequently, the wafer W having been positioned by the positioning table 52 is transferred by the conveyance arm 61 of the wafer conveyance unit 60 onto the mount table 72 of the mount unit 70. In this state, the circuit surface of the wafer W is located below, and is surrounded by the ring frame R (see FIG. 7).

The mount table 72 is also provided with a suction member capable of attraction (not shown) so that the protective tape P side of wafer W is attracted and sustained through the action of a negative pressure.

In this way, the wafer W and the ring frame R which surround the wafer W, are attracted and sustained on the upper surface of the mount table 72 by suction. Thereafter, dicing tape T having been precut into the morphology of ring frame is stuck to the upper surface thereof by dicing tape delivery unit 80. Thus, sticking item E is formed.

The dicing tape delivery unit 80 is constructed in such a fashion that, as shown in FIG. 8(A), dicing tapes T having been precut and stuck to release material D at given intervals are peeled from the release material D by sharply folding back the release material D with an acute angle at a front edge portion of peel plate 82.

Each dicing tape T thus having been peeled from the release material D is stuck to both the ring frame R and the wafer W by means of press roller 84.

On the other hand, the mount table 72, as shown in FIG. 8, is movable along guide rail 85 provided so as to permit right and left movement. Further, the mount table 72 is movable in a direction that it is drawn close to or apart from the dicing tape delivery unit 80.

Accordingly, as shown in FIG. 8(A), the mount table 72 is moved along the guide rail 85 in such a direction that the mount table 72 is drawn close to the peel plate 82. Consequently, one edge portion of the ring frame R is located in the vicinity of the front edge portion of the peel plate 82.

Then, each dicing tape T is peeled from the release material D by sharply folding back the release material D with an acute angle at the front edge portion of the peel plate 82. Thereafter, as shown in FIG. 8(B), the mount table 72 is elevated by means of a vertical cylinder (not shown), so that the front edge portion of the dicing tape T is stuck under pressure to the ring frame R by means of the press roller 84.

Further, as shown in FIG. 8(C), the mount table 72 is moved along the guide rail 85 in such a direction that the mount table 72 is drawn apart from the peel plate 82. Futher, each dicing tape T is stuck, by means of the press roller 84, to the wafer W and the ring frame R which surrounds the wafer W. As a result, the sticking item E (FIG. 7) consisting of the wafer W and the ring frame R united together is formed.

Thereafter, as shown in FIGS. 1 and 5, the ring frame R portion round the periphery of the wafer W is attracted and sustained by means of suction pad 94 of arm part 92 of rotary arm unit 90 arranged beside the mount table 72. The arm part 92 of the rotary arm unit 90 is rotated by 180°, so that the surface of wafer W having the protective tape P stuck thereto comes to lie upside.

As shown in FIG. 1, the sticking item E consisting of the wafer W united with the ring frame R by means of the dicing tape T is attracted, sustained and moved by means of another conveyance member 95 which is movable along conveyance rail 91. As a result, the sticking item E is disposed on peeling table part 112 of protective tape peeling unit 110.

The protective tape peeling unit 110, as shown in FIGS. 1 and 9 to 14, comprises peeling table part 112, tape delivery part 114, peeling head part 116 as moving means and heater cutter part 118 as bonding/cutting means.

The peeling table part 112 includes peeling table 122 which is movable on guide rail 172 (FIG. 1) in the cross direction (Y-axis direction). In addition, the peeling table 122 on its upper surface is also provided with a suction member capable of attraction which is porous or has suction holes (not shown). As a result, the sticking item E consisting of the wafer W united with the ring frame R by means of the dicing tape T can be attracted and sustained by application of a negative pressure.

In the tape delivery part 114, as shown in FIGS. 5 and 9 to 13, peeling tape S is let out, interposed between pinch roller 126 and guide roller 128 and fed to tape receiving plate 132. On this tape receiving plate 132, the peeling tape S is pressed by means of vertically movable tape presser plate 134. The tape delivery part 114 is so constructed that it is movable in the vertical direction (Z-axis direction).

As for the peeling tape S, for example, a heat resistant film, such as a polyethylene terephthalate (PET) film, overlaid with a heat sensitive adhesive layer, or peeling tape S per se having heat sensitivity can be used.

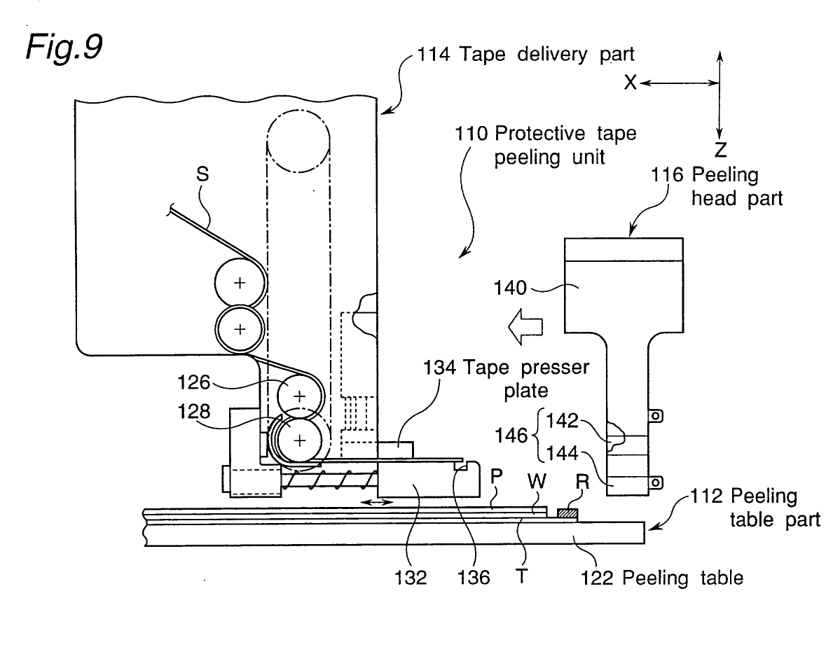

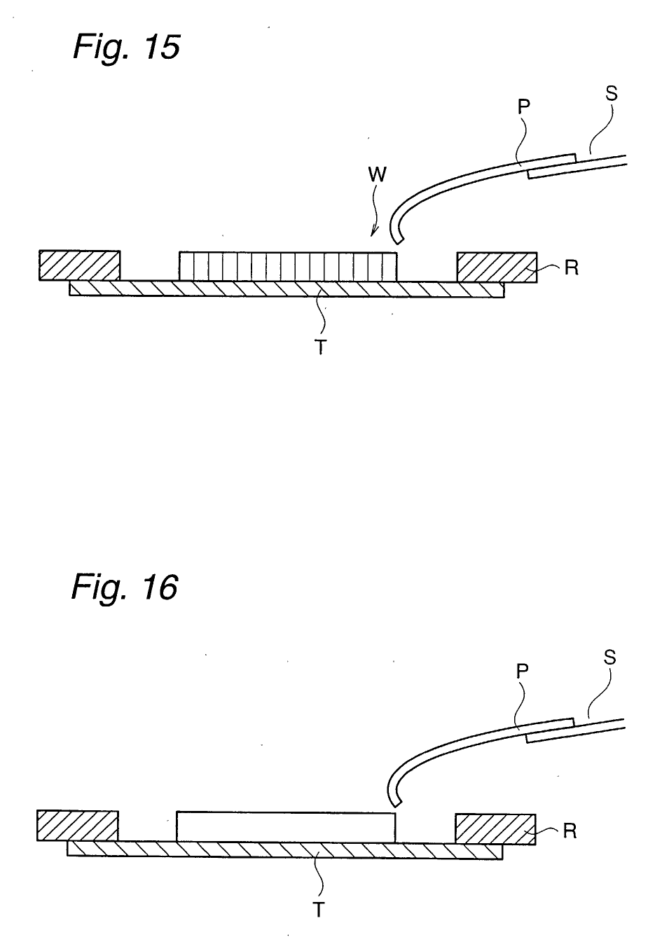

The peeling head part 116, as shown in FIGS. 9 to 15, includes head 140 and is movable in the right and left direction (X-axis direction). The head 140 is provided with chuck 146 consisting of upper jaw 142 and lower jaw 144 and is vertically moved so that the chuck 146 can be opened and closed.

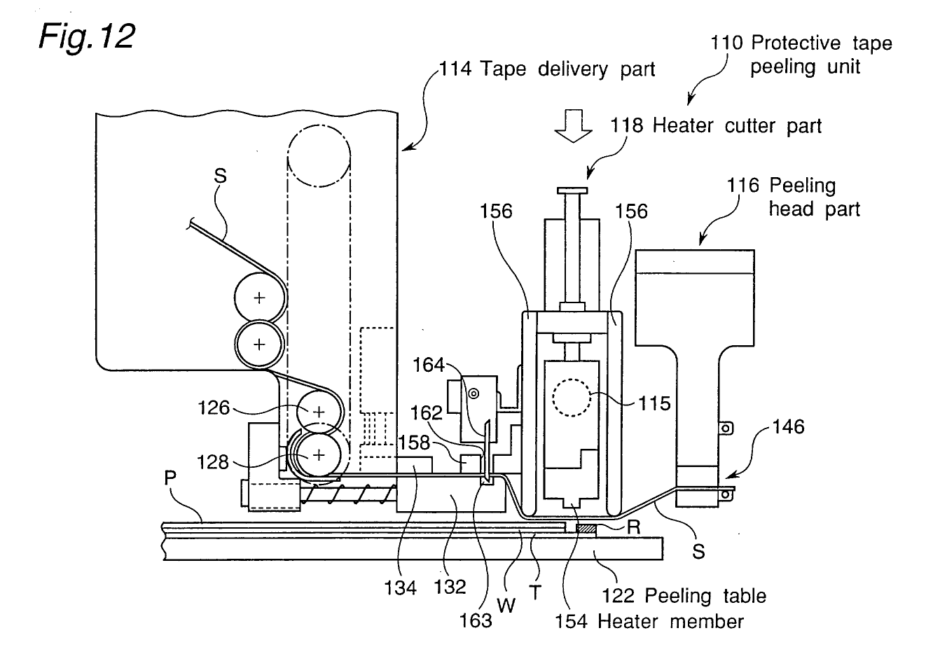

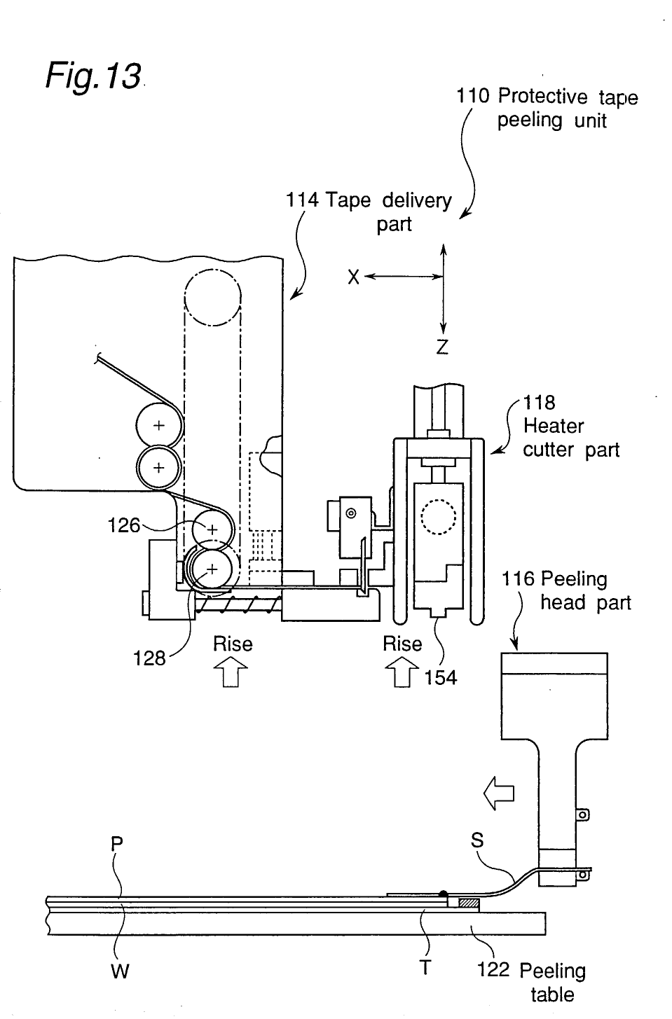

The heater cutter part 118, as shown in FIGS. 12 and 13, is provided with heater member 154 including vertically movable heater 115.

Front and rear sides of the heater cutter part 118 are provided with tape presser guides 156, 156. The rear side of the heater cutter part 118 is further provided with tape presser 158 and also provided with cutter blade 164 which is moved in the cross direction along clearance 162 of the tape presser 158.

The thus constructed protective tape peeling unit 110 is operated as shown in FIGS. 9 to 14.

As shown in FIG. 9, the peeling tape S is fed until reaching cutter groove 136, and simultaneously the peeling table 122 is moved until reaching a position under the tape delivery part 114. Then, the peeling head part 116 is moved in such a direction that the detaching head part 116 is drawn close to the tape delivery part 114. During that period, the chuck 146 is held open.

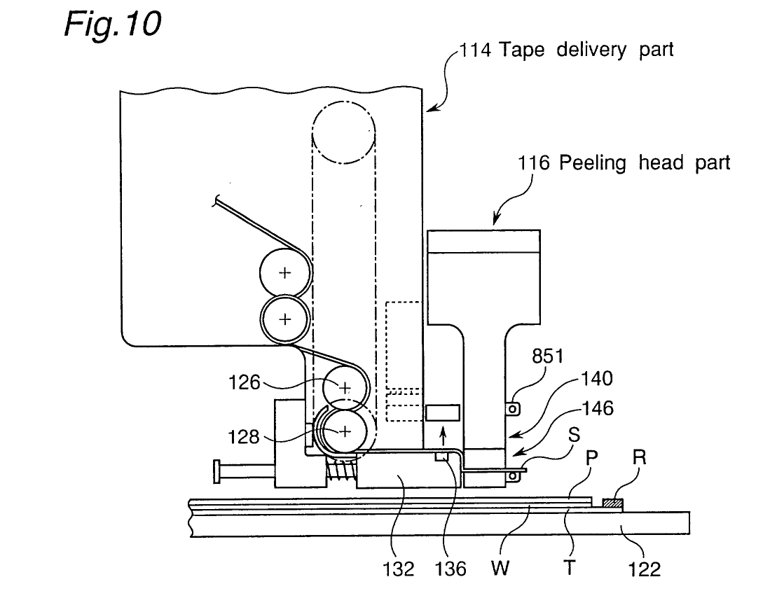

As show in FIG. 10, the peeling head part 116 presses the tape receiving plate 132. Simultaneously, upon detection of the front end of the peeling tape S, the chuck 146 is closed so that the peeling tape S is interposed between its upper and lower jaws, and the tape presser plate 134 is raised.

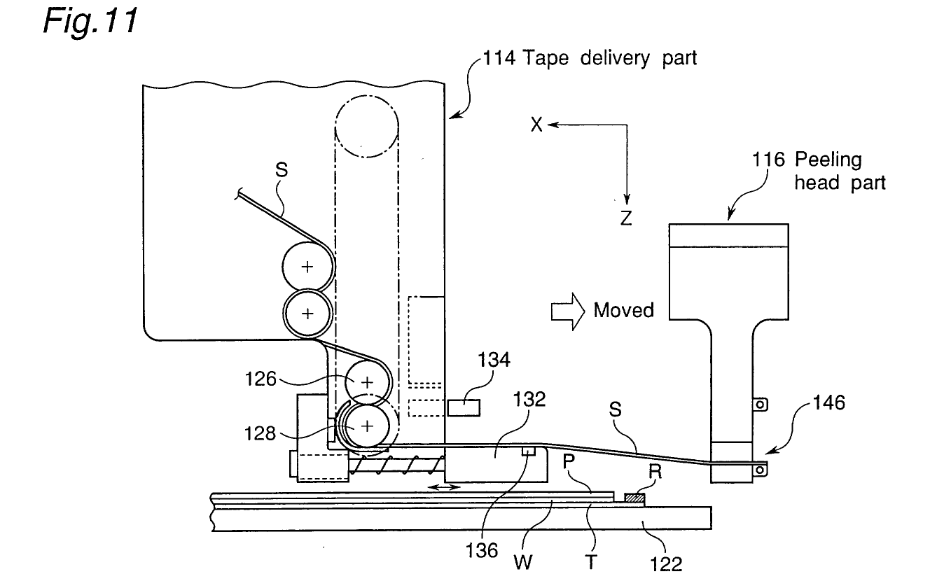

Further, as shown in FIG. 11, the peeling head part 116 is moved in such a direction that the peeling head part 116 is drawn apart from the tape delivery part 114 so that the peeling tape S is pulled out. Thereafter, as shown in FIG. 12, the heater cutter part 118 is caused to descend so that the peeling tape S is pressed by means of the tape presser 158 and the tape presser guides 156, 156. Simultaneously, the peeling tape S is bonded by thermal fusion to the protective tape P of the wafer W surface with the use of heat from the heater 115 by means of the heater member 154. The peeling tape S is cut to given lengths by moving the cutter blade 164 in the cross direction along the clearance 162 of the tape presser 158. It is preferred that the bonding point lie in the vicinity of an edge of the wafer W, for example, within about 3 mm from the extreme edge of the wafer W.

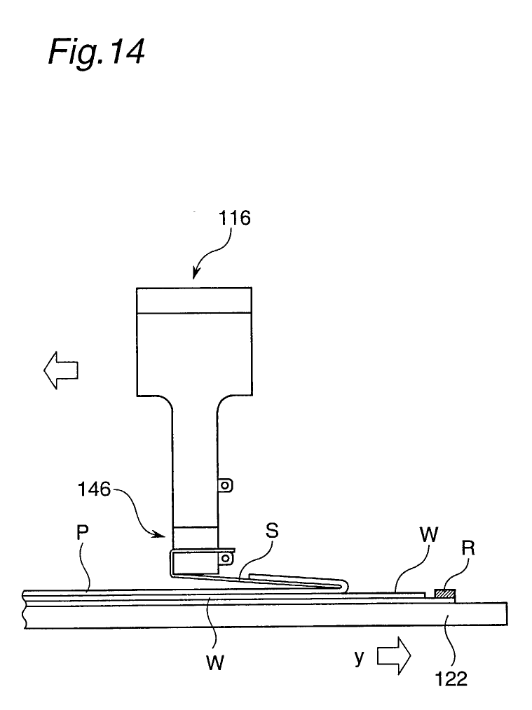

The tape delivery part 114 and the heater cutter part 118 are raised as shown in FIG. 13 and, thereafter, the peeling head part 116 and the peeling table 122 are moved in such directions that these are drawn apart from each other as shown in FIG. 14. As a result, the protective tape P of the wafer W surface can be peeled from the wafer W surface by means of the peeling tape S.

The thus peeled tape S and protective tape P, although not shown, are dropped into a disposal box not shown by opening the chuck 146 of the detaching head part 116 and simultaneously conducting an air blow from above so that stocking of the detached peeling tape S and protective tape P are attained.

The wafer W in which the protective tape P is peeled from the wafer W surface by means of the protective tape peeling unit 110 is attracted and sustained by the peeling table 122. Consequently, the wafer W is caused to pass through second ultraviolet irradiation unit 180 and transferred to ejection pusher unit 190.

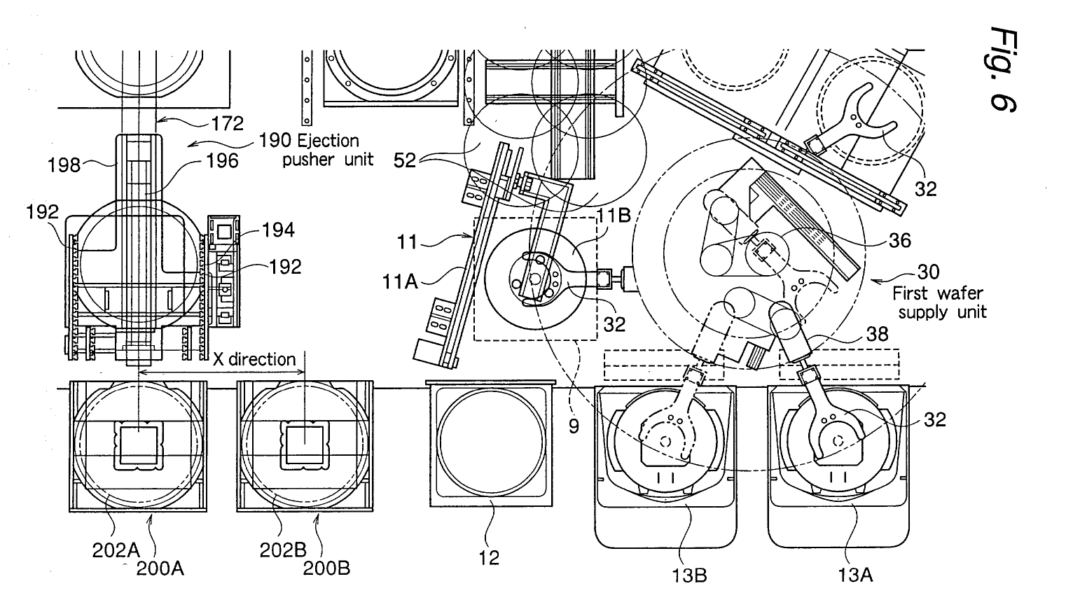

The peeling table 122, as shown in FIGS. 1 and 5, is movable in the cross direction (Y-axis direction) on guide rail 172 which extends in the cross direction to ejection roller part 192 (FIG. 6) of the ejection pusher unit 190 of the protective tape peeling unit 110.

The second ultraviolet irradiation unit 180 has the same fundamental structure as that of the first ultraviolet irradiation unit 40 (processing wafer W free of ring frame) except that the sticking item E consisting of the wafer W stuck to the ring frame R is processed. Ultraviolet light from ultraviolet lamp tubes is irradiated upward.

Thus, the wafer W of the sticking item E which is united with ring frame R on the peeling table 122 of the protective tape peeling unit 110 is attracted and sustained by the peeling table 122 at the ring frame R portion thereof. In this state, the wafer W is moved along the guide rail 172 so that it passes above the second ultraviolet irradiation unit 180.

Consequently, where the dicing tape T is one having an ultraviolet curable pressure sensitive adhesive, the dicing tape T is exposed to ultraviolet light by means of the second ultraviolet irradiation unit 180 so that the pressure sensitive adhesive of the dicing tape T is cured and the adherence of the pressure sensitive adhesive can be lowered. Therefore, in the subsequent pickup step wherein divided individual chips are picked up, the chips can be easily picked up from the dicing tape T without the occurrence of breakage, damage or cracking of chips.

The wafer W thus having passed above the second ultraviolet irradiation unit 180 is transferred onto ejection roller parts 192, 192 of the ejection pusher unit 190.

The ejection pusher unit 190, as shown in FIGS. 1 and 6, is provided with a right and left pair of side guide members 194. The internal surfaces of the pair of side guide members 194 are provided with ejection roller parts 192, 192 each composed of a plurality of rollers arranged with constant spacings. Only the ring frame R portion is brought into contact with the ejection roller parts 192, 192, so that the breakage of wafer W can be avoided.

Moving cylinder 196 is disposed upstream of the ejection roller parts 192, 192 The moving cylinder 196 is slidable in the cross direction under the guidance by means of guide rod 198. Pusher member (not shown) secured to an upper side of the moving cylinder 196 pushes downstream the wafer W having been transferred onto the ejection roller parts 192, 192 in accordance with the movement of the moving cylinder 196. As a result, the sticking item E is accommodated in accommodation cassette 202A or 202B of unloader unit 200A or 200B disposed downstream. As shown in FIG. 1, like the wafer cassettes 13A, 13B, two accommodation cassettes 202A, 202B are disposed in parallel, thereby enabling continuous operation. In this construction, as indicated by the arrow of FIG. 1, the ejection pusher unit 190 is moved in the longitudinal direction (X-axis direction) so that wafer W can be accommodated in either of the accommodation cassettes 202A, 202B disposed in parallel.

These unloader units 200A, 200B are vertically movable so that accommodation shelves of the accommodation cassettes 202A, 202B can be located at positions corresponding to the heights of the ejection roller parts 192, 192 of the ejection pusher unit 190.

The wafer W of each sticking item accommodated in the accommodation cassettes 202A, 202B is divided into a multiplicity of chips in the subsequent step. The divided chips are picked up and mounted on, for example, electronic component substrates by means of a separate die bonding unit (not shown).

As apparent from the foregoing, in the instance (1) in which both the protective tape P and the dicing tape T are those having an ultraviolet curable pressure sensitive adhesive and in which the wafer W having been divided into a multiplicity of chips by predicing is formed into the sticking item E consisting of the wafer W united with the ring frame R by means of the dicing tape T with the use of the wafer transfer apparatus 1 and in which chips are picked up (i.e. die bonding) after this formation of the sticking item, both the first ultraviolet irradiation unit 40 and the second ultraviolet irradiation unit 180 are operated, and the wafer W is passed through both the first ultraviolet irradiation unit 40 and the second ultraviolet irradiation unit 180.

However, in the instance (2) in which both the protective tape P and the dicing tape T are not those having an ultraviolet curable pressure sensitive adhesive and are common pressure sensitive adhesive tapes, both the first ultraviolet irradiation unit 40 and the second ultraviolet irradiation unit 180 are not operated.

Further, in the instance (3) in which the protective tape P is one having an ultraviolet curable pressure sensitive adhesive while the dicing tape T is not one having an ultraviolet curable pressure sensitive adhesive and the dicing tape T is common pressure sensitive adhesive tape, the first ultraviolet irradiation unit 40 is operated while the second ultraviolet irradiation unit 180 is not operated.

Still further, in the instance (4) in which the protective tape P is not one having an ultraviolet curable pressure sensitive adhesive and is common pressure sensitive adhesive tape while the dicing tape T is one having an ultraviolet curable pressure sensitive adhesive, the first ultraviolet irradiation unit 40 is not operated while the second ultraviolet irradiation unit 180 is operated.

As shown in FIG. 16, in the instance (5) in which both the protective tape P and the dicing tape T are those having an ultraviolet curable pressure sensitive adhesive and in which common wafer W not diced into a multiplicity of chips is stuck to the ring frame R by means of a pressure sensitive adhesive sheet and thereafter diced (postdicing), only the first ultraviolet irradiation unit 40 is operated without the operating of the second ultraviolet irradiation unit 180 in order to, at the time of dicing, maintain the adherence between the dicing tape T and the wafer W, thereby avoiding breakage of the wafer W.

By virtue of this construction, even in the conventional postdicing processing, the pressure sensitive adhesive of the protective tape P is cured and the adhesive thereof is lowered by exposing the protective tape P to ultraviolet light with the use of the first ultraviolet irradiation unit 40. Consequently, in the step of peeling the protective tape P, the protective tape P can be easily peeled from the wafer W without the occurrence of breakage, damage or cracking of wafer W.

Moreover, because the second ultraviolet irradiation unit 180 is not operated, dicing can be performed with the adherence between dicing tape T and wafer W maintained at the dicing step.

The present invention is in no way limited to the hereinabove described Examples. Although the above Examples describe processing of wafer W, the present invention can be applied to, for example, other plate members such as those of ceramic and glass or package channels. Thus, various modifications can be made to the present invention as far as the objects of the present invention are not departed from.

### Effect of the Invention

In the present invention, the division lines of chipped wafer is recognized and a position regulation of the wafer in longitudinal and lateral directions (X- and Y-directions) and direction of rotation (θ-direction) is conducted so that the wafer is located at given reference position. As a result, at the die bonding step, accurate die bonding can be effected. Also, the relevant transfer operation and protective tape peeling operation can be continuously carried out without conveyance using a wafer carrier, so that operation efficiency can be enhanced.

Moreover, where the protective tape is one having an ultraviolet curable pressure sensitive adhesive, the protective tape is exposed to ultraviolet light with the use of the first ultraviolet irradiation unit so that the adherence of the protective tape can be lowered. As a result, in the step of peeling the protective tape, the protective tape can be easily peeled from the wafer without the occurrence of breakage, damage or cracking of wafer.

Further, where the dicing tape is one having an ultraviolet curable pressure sensitive adhesive, the dicing tape is exposed to ultraviolet light with the use of the second ultraviolet irradiation unit so that the adherence of the dicing tape can be lowered. As a result, in the subsequent pickup step wherein, after the division into a multiplicity of chips, the chips are picked up, the chips can be easily picked up from the dicing tape without the occurrence of breakage, damage or cracking of chips.

Still further, the present invention enables selectively performing exposure of the protective tape to ultraviolet light by means of the first ultraviolet irradiation unit and exposure of the dicing tape to ultraviolet light by means of the second ultraviolet irradiation unit Therefore, the present invention can be applied to both cases of the conventional postdicing processing and the predicing processing. Moreover, irrespective of the types of employed protective tape and dicing tape, the wafer having the protective tape stuck thereto can be continuously and automatically transferred to the dicing tape and the ring frame without the occurrence of breakage damage or cracking of wafer and also peeling of the protective tape can be accomplished. Therefore, the present invention ensures enhanced general applicability.

Still further, the present invention provides the wafer transfer apparatus of enhanced general applicability which can be joined with a grinder (inline docking) so as to enable use of wafers prediced by the grinder and which can also be used alone without being joined with a grinder as an off-line (stand alone) capable of taking out wafers from a wafer cassette wherein wafers are accommodated or a wafer packing container wherein wafers are accommodated and processing them. As apparent from the above, the present invention is extremely advantageous one capable of exerting a variety of peculiar striking functions and effects.

What is claimed is:

1. A wafer transfer apparatus for sticking a wafer, in which a protective tape is stuck to its surface, to a ring frame by means of a dicing tape, the wafer transfer apparatus comprising:
a first ultraviolet irradiation unit capable of irradiating and exposing ultraviolet light to the protective tape;
a positioning unit capable of disposing a wafer having a protective tape stuck to a surface thereof on a positioning table and conducting a position regulation of the wafer in longitudinal and lateral directions and direction of rotation to thereby locate the wafer at given reference position;
a mount unit capable of disposing on a mount table the wafer having the protective tape stuck thereto after having been located at the given reference position by the positioning unit, and capable of sticking a dicing tape to both the wafer at its back and a ring frame arranged so as to surround the wafer, thereby uniting the wafer and the ring frame together;
a protective tape peeling unit capable of disposing on a protective tape peeling table the wafer having the dicing tape stuck to the back thereof and thus having been united with the ring frame by the mount unit, capable of bonding an end of a peeling tape to an end of the protective tape provided on the surface of the wafer, and capable of pulling the peeling tape so that the protective tape is peeled from the wafer surface; and
a second ultraviolet irradiation unit capable of irradiating and exposing ultraviolet light to the dicing tape of the wafer having been united with the ring frame by means of the dicing tape after peeling of the protective tape from the wafer surface by the protective tape peeling unit.

2. The wafer transfer apparatus as claimed in claim 1, wherein selection from among performing both exposure of the protective tape to ultraviolet light by the first ultraviolet irradiation unit and exposure of the dicing tape to ultraviolet light by the second ultraviolet irradiation unit, performing either of the exposures and not performing both of the exposures is operated.

3. The wafer transfer apparatus as claimed in claim 1 or 2, wherein the protective tape is one having an ultraviolet curable pressure sensitive adhesive, and ultraviolet light is exposed to the protective tape by the first ultraviolet irradiation unit.

4. The wafer transfer apparatus as claimed in any of claims 1 to 3, wherein the dicing tape is one having an ultraviolet curable pressure sensitive adhesive and ultraviolet light is exposed to the dicing tape by the second ultraviolet irradiation unit.

5. The wafer transfer apparatus as claimed in any of claims 1 to 4, wherein the wafer is one having been divided into a multiplicity of chips and having the protective tape stuck to the surface thereof, and both exposure of the protective tape to ultraviolet light by the first ultraviolet irradiation unit and exposure of the dicing tape to ultraviolet light by the second ultraviolet irradiation unit are operated.

6. The wafer transfer apparatus as claimed in any of claims 1 to 4, wherein the wafer is one not having been divided into a multiplicity of chips but having the protective tape stuck to the surface thereof, and only exposure of the protective tape to ultraviolet light by the first ultraviolet irradiation unit is operated.

7. The wafer transfer apparatus as claimed in any of claims 1 to 6, wherein conveyance means for conveying wafers to be processed from outside is attached to the first ultraviolet irradiation unit.

8. The wafer transfer apparatus as claimed in any of claims 1 to 7, wherein the first ultraviolet irradiation unit is provided with a wafer conveyance unit capable of taking out wafers from a wafer cassette wherein wafers are accommodated, and capable of carrying the wafers to the first ultraviolet irradiation unit.

9. The wafer transfer apparatus as claimed in claim 8, wherein the first ultraviolet irradiation unit is provied with wafer takeout means capable of taking out wafers from a wafer packing container wherein wafers are accommodated, and capable of delivering the wafers to the wafer conveyance unit.
